(19) United States
(12) Patent Application Publication
(10) Pub. No.: US 2011/0128074 A1
(43) Pub. Date: Jun. 2, 2011

(54) PRIMITIVE CELL AND SEMICONDUCTOR DEVICE

(75) Inventor: Fumio NAKANO, Kanagawa (JP)

(73) Assignee: Renesas Electronics Corporation

(21) Appl. No.: 12/953,786

(22) Filed: Nov. 24, 2010

(30) Foreign Application Priority Data
Nov. 27, 2009 (JP) 2009-269824

(51) Int. Cl. H03H 11/00

(52) U.S. Cl. 327/594

(57) ABSTRACT

A primitive cell according to the present invention includes: an internal circuit; a power supply wire that applies a power supply voltage to the internal circuit; and a ground wire that applies a ground voltage to the internal circuit, in which the power supply wire and the ground wire are arranged so as to be localized in one side of outer peripheral sides of the cell.

### INCORPORATION BY REFERENCE

This application is based upon and claims the benefit of priority from Japanese patent application No. 2009-269824, filed on Nov. 27, 2009, the disclosure of which is incorporated herein in its entirety by reference.

### BACKGROUND

1. Field of the Invention

The present invention relates to a primitive cell and a semiconductor device, and more particularly to a primitive cell including an internal circuit and a power supply wire supplying electric power to the internal circuit, and a semiconductor device including the primitive cell.

2. Description of Related Art

In recent years, a cell-based semiconductor device (hereinafter referred to as a cell-based IC (Integrated Circuit)) has been suggested for the purpose of reducing the development period. In the cell-based IC, a functional block is constituted by combining basic cells (e.g., inverters, NAND circuits, NOR circuits, flip-flop circuits) where minimum functions constituting a logic circuit are put into cells.

Furthermore, in recent years, System in Package (SiP) has been proposed as a technique of reducing an area for mounting a semiconductor device. While a plurality of semiconductor chips are mounted on a single package in SiP, the area of mounting the semiconductor device can be reduced by stacking the semiconductor chips. Further, in SiP, a plurality of chips manufactured by different semiconductor processes can be mounted on a single package. However, when an analog IC and a digital IC are mounted in SiP, electromagnetic (EMI) noise that is generated in the digital IC may influence on properties of the analog IC.

Now, one example of the technique of reducing EMI noise in this cell-based IC is disclosed in Japanese Unexamined Patent Application Publication No. 2000-183286. FIG. 8 shows a schematic diagram of a basic cell (hereinafter referred to as a primitive cell) disclosed in Japanese Unexamined Patent Application Publication No. 2000-183286. FIG. 8 shows a gate circuit 102 and a bypass capacitor 103 as a primitive cell 101. In Japanese Unexamined Patent Application Publication No. 2000-183286, the bypass capacitor 103 is arranged adjacent to the gate circuit 102 operated by periodic signals (e.g., clock signals), thereby setting the distance of a power supply wire 104 of the bypass capacitor 103 and the gate circuit 102 to the shortest distance. Accordingly, in Japanese Unexamined Patent Application Publication No. 2000-183286, the impedance of the power supply wire 104 seen from the gate circuit 102 is reduced and EMI noise can be reduced.

### SUMMARY

However, in the primitive cell 101 disclosed in Japanese Unexamined Patent Application Publication No. 2000-183286, the power supply wire 104 and the ground wire 105 of each of the primitive cells are arranged in the upper part and the lower part of the cell. Thus, in the primitive cell 101, a current path from the power supply wire 104 to the ground wire 105 forms a loop, and EMI noise may be generated in this loop.

In order to describe this problem further in detail, FIG. 9 shows a schematic diagram of a planar layout of a semiconductor device constituting a functional circuit using the primitive cell 101. Note that FIG. 9 is created by the present inventor for the purpose of explaining the problem.

As shown in FIG. 9, when a functional circuit is constituted using the primitive cell 101, the primitive cells are arranged in line in a region between the power supply wire 104 and the ground wire 105. Further, the power supply wire 104 is connected to a power supply pad VP arranged on a semiconductor chip, and the ground wire 105 is connected to a ground pad GP arranged on the semiconductor chip. Then, the current consumed in the gate circuit 102 is supplied from the power supply wire 104, flows through a current path CP to be discharged to the ground wire 105. Further, a part of the current consumed in the gate circuit 102 is supplied from the bypass capacitor 103 arranged adjacent thereto.

As shown in FIG. 9, in the primitive cell 101, the power supply wire 104 and the ground wire 105 are arranged with the primitive cells interposed therebetween. Thus, the current path CP forms a loop. Thus, in the left-side loop in the drawing, a magnetic field is generated from the front side to the back side of the drawing inside of the loop, and a magnetic field is generated from the back side to the front side of the drawing outside of the loop. Further, in the right-side loop in the drawing, a magnetic field is generated from the back side to the front side of the drawing toward the inside of the loop, and a magnetic field is generated from the front side to the back side of the drawing toward the outside of the loop. In the primitive cell 101 disclosed in Japanese Unexamined Patent Application Publication No. 2000-183286, the size of the loop of the current path shown in FIG. 9 is large, which means that the magnetic field generated in the loop is large and EMI noise cannot be sufficiently reduced.

A first exemplary aspect of an embodiment of the present invention is a primitive cell including: an internal circuit; a power supply wire that applies a power supply voltage to the internal circuit; and a ground wire that applies a ground voltage to the internal circuit, in which the power supply wire and the ground wire are arranged so as to be localized in one side of outer peripheral sides of the cell.

A second exemplary aspect of an embodiment of the present invention is a semiconductor device including a primitive cell, the primitive cell including: an internal circuit; a power supply wire that applies a power supply voltage to the internal circuit; and a ground wire that applies a ground voltage to the internal circuit; in which the power supply wire and the ground wire are arranged so as to be localized in one side of outer peripheral sides of the cell, and a plurality of primitive cells constitute a functional circuit.

The primitive cell and the semiconductor device according to the present invention include the power supply wire and the ground wire localized in one side of the cell. Accordingly, the size of the loop formed by the path of the current flowing through the primitive cell is limited to the size of one primitive cell. Accordingly, the primitive cell and the semiconductor device according to the present invention are able to reduce EMI noise generated by the loop formed by the current path.

A primitive cell and a semiconductor device according to the present invention achieve a cell-based IC with reduced EMI noise.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a circuit diagram showing one example of a circuit (inverter) of a primitive cell according to a first exemplary embodiment of the present invention;

FIG. 2 is a schematic diagram of a layout showing one example of the primitive cell including the circuit shown in FIG. 1 as an internal circuit;

FIG. 3 is a circuit diagram showing one example of a circuit (NAND circuit) of the primitive cell according to the first exemplary embodiment of the present invention;

FIG. 4 is a schematic diagram of a layout showing one example of the primitive cell including the circuit shown in FIG. 3 as an internal circuit;

FIG. 5 is a circuit diagram showing one example of a circuit (SR flip-flop circuit) of the primitive cell according to the first exemplary embodiment of the present invention;

FIG. 6 is a schematic diagram of a layout showing one example of the primitive cell including the circuit shown in FIG. 5 as an internal circuit;

FIG. 7 is a schematic diagram of a layout showing one example of a semiconductor device formed by using the primitive cells according to the first exemplary embodiment;

FIG. 8 is a schematic diagram showing a planar layout of a primitive cell disclosed in Japanese Unexamined Patent Application Publication No. 2000-183286; and

FIG. 9 is a diagram for explaining a problem of a semiconductor device formed by using the primitive cell shown in FIG. 8.

### DETAILED DESCRIPTION OF THE EXEMPLARY EMBODIMENTS

### First Exemplary Embodiment

Hereinafter, a first exemplary embodiment of the present invention will be described with reference to the drawings. The present invention relates to a basic cell used in a cell-based IC (hereinafter referred to as a primitive cell), and a semiconductor device designed using the primitive cell. The primitive cell is a minimum constitutional unit of a functional circuit that achieves a predetermined function in the semiconductor device, and includes at least one of an inverter circuit, a NAND circuit, a NOR circuit, a flip-flop circuit and so on. In summary, the primitive cell includes at least two transistors, and is the minimum constitutional unit of the functional circuit. The following description will be made of an inverter circuit, a NAND circuit, and a set reset flip-flop circuit (hereinafter referred to as a SRFF circuit) as an example of the primitive cell. The circuit realized in the primitive cell is not limited to the above circuit.

First, a circuit diagram of an inverter circuit is shown in FIG. 1. As shown in FIG. 1, an inverter circuit INV includes a PMOS transistor MP1 and an NMOS transistor MN1. The PMOS transistor MP1 has a source connected to a power supply wire VDD, and a drain connected to a drain of the NMOS transistor MN1. Then, a connection node of the drain of the PMOS transistor MP1 and the drain of the NMOS transistor MN1 serves as an output terminal OUT. Further, a source of the NMOS transistor MN1 is connected to a ground wire GND. Then, an input terminal IN is connected to a gate of the NMOS transistor MN1 and a gate of the PMOS transistor MP1.

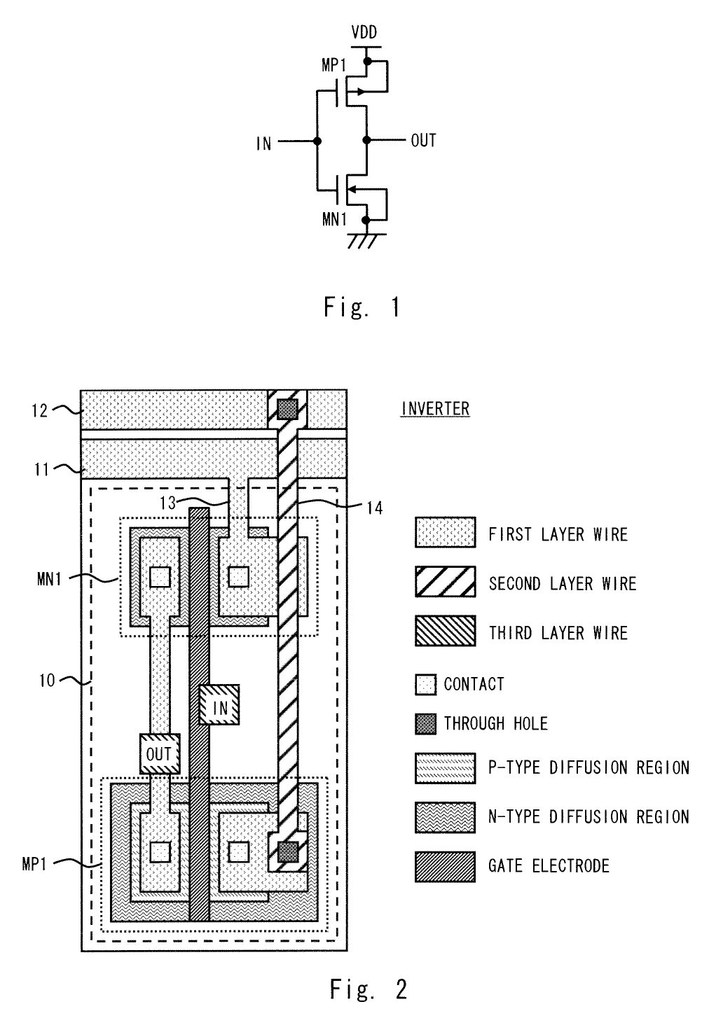

Further, FIG. 2 shows a schematic diagram of a planar layout of the primitive cell including the inverter circuit INV shown in FIG. 1 as an internal circuit. The primitive cell shown in FIG. 2 includes the PMOS transistor MP1 and the NMOS transistor MN1 constituting the inverter circuit formed in an internal circuit forming region 10 in which the internal circuit is formed. Further, the input terminal IN and the output terminal OUT are formed in the internal circuit. The input terminal IN and the output terminal OUT are connected to an input terminal or an output terminal of another primitive cell by wires formed in the upper layer of the primitive cell. The internal circuit constitutes a transistor by a diffusion region formed of a P-type semiconductor (P-type diffusion region), a diffusion region formed of an N-type semiconductor (N-type diffusion region), and a gate electrode, and the wiring is formed of a first layer wire to a third layer wire, a contact, and a through hole.

Further, as shown in FIG. 2, the primitive cell according to the present invention includes a ground wire 11 and a power supply wire 12. The ground wire 11 applies a ground voltage to the internal circuit, and the power supply wire 12 applies a power supply voltage to the internal circuit. Then, the ground wire 11 and the power supply wire 12 localize in one side of the sides of the primitive cell. Further, the ground wire 11 and the power supply wire 12 are arranged so as to traverse the primitive cell. Although the ground wire 11 and the power supply wire 12 are adjacent to each other in FIG. 2, the ground wire 11 and the power supply wire 12 may have other structure as long as they localize in one side of the primitive cell. For example, the ground wire 11 and the power supply wire 12 may be overlapped with each other. Further, the ground wire 11 includes a branch ground wire 13 that connects the ground wire 11 and the internal circuit. The branch ground wire 13 draws the ground voltage supplied through the ground wire 11 into the internal circuit. Further, the power supply wire 12 includes a branch power supply wire 14 that connects the power supply wire 12 and the internal circuit. The branch power supply wire 14 draws the power supply voltage supplied through the power supply wire 12 into the internal circuit.

In the primitive cell shown in FIG. 2, the current that flows through the internal circuit from the power supply wire 12 is discharged to the ground wire 11 through the source and the drain of the PMOS transistor MP1, and the drain and the source of the NMOS transistor MN1. At this time, since the ground wire 11 and the power supply wire 12 localize in one side of the sides of the primitive cell, the size of the loop formed by the current flowing through the primitive cell is smaller than the size of a single primitive cell.

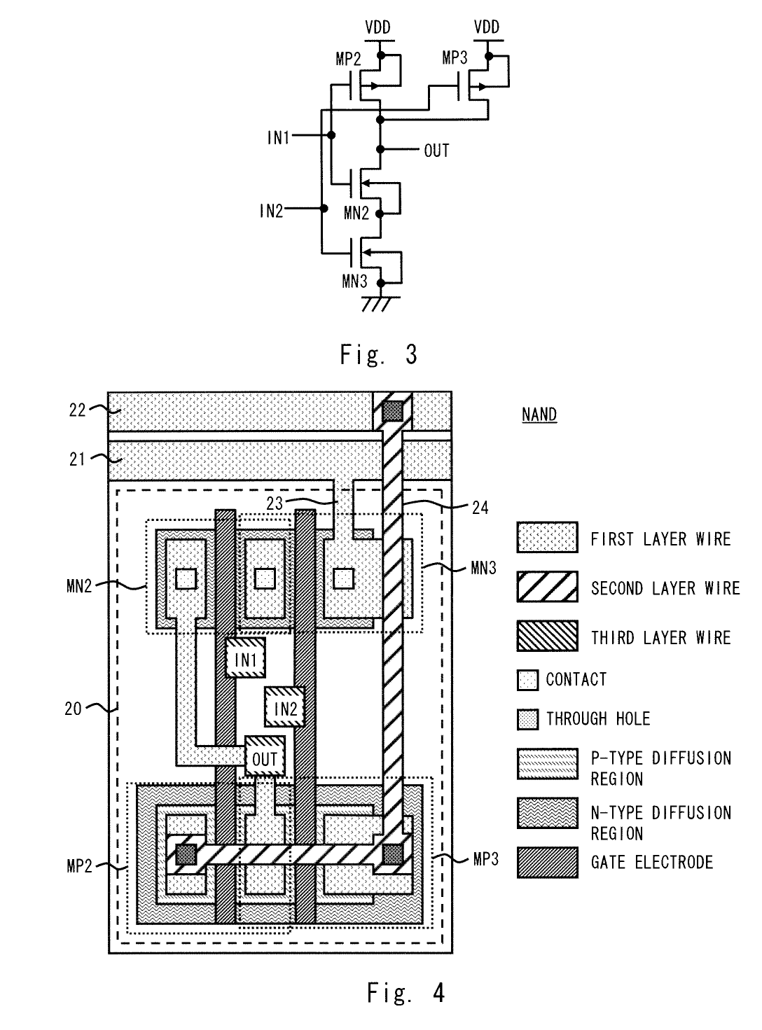

Next, FIG. 3 shows a circuit diagram of a NAND circuit. As shown in FIG. 3, the NAND circuit includes PMOS transistors MP2, MP3, and NMOS transistors MN2, MN3. The PMOS transistors MP2 and MP3 each have a source connected to the power supply wire VDD, and a drain connected to a drain of the NMOS transistor MN2. A connection node of the drain of each of the PMOS transistors MP2 and MP3 and the drain of the NMOS transistor MN2 serves as the output terminal OUT. Further, a source of the NMOS transistor MN2 is connected to a drain of the NMOS transistor MN3. Further, a source of the NMOS transistor MN3 is connected to the ground wire GND. Then, a first input terminal IN1 is connected to a gate of the NMOS transistor MN2 and a gate of the PMOS transistors MP2. Further, a second input terminal IN2 is connected to a gate of the NMOS transistor MN3 and a gate of the PMOS transistor MP3.

FIG. 4 shows a schematic diagram of a planar layout of the primitive cell including the NAND circuit shown in FIG. 3 as the internal circuit. The primitive cell shown in FIG. 4 includes the PMOS transistors MP2 and MP3 and the NMOS transistors MN2 and MN3 constituting the NAND circuit formed in an internal circuit forming region 20 where the internal circuit is formed. Further, the first input terminal IN1, the second input terminal IN2, and the output terminal OUT are formed in the internal circuit. The first input terminal IN1, the second input terminal IN2, and the output terminal OUT are connected to an input terminal or an output terminal of another primitive cell by wires formed in the upper layer of the primitive cell. Note that the internal circuit constitutes a transistor by a diffusion region formed of a P-type semiconductor (P-type diffusion region), a diffusion region formed of an N-type semiconductor (N-type diffusion region), and a gate electrode, and the wiring is formed of a first layer wire to a third layer wire, a contact, and a through hole.

Further, as shown in FIG. 4, the primitive cell according to the present invention includes a ground wire 21 and a power supply wire 22. The ground wire 21 applies the ground voltage to the internal circuit, and the power supply wire 22 applies the power supply voltage to the internal circuit. Then, the ground wire 21 and the power supply wire 22 localize in one side of the sides of the primitive cell. Further, the ground wire 21 and the power supply wire 22 are arranged so as to traverse the primitive cell. Although the ground wire 21 and the power supply wire 22 are adjacent in the example shown in FIG. 4, the ground wire 21 and the power supply wire 22 may have other structure as long as they localize in one side of the primitive cell. For example, the ground wire 21 and the power supply wire 22 may be overlapped with each other. Further, the ground wire 21 includes a branch ground wire 23 that connects the ground wire 21 and the internal circuit. The branch ground wire 23 draws the ground voltage supplied through the ground wire 21 into the internal circuit. Further, the power supply wire 22 includes a branch power supply wire 24 that connects the power supply wire 22 and the internal circuit. The branch power supply wire 24 draws the power supply voltage supplied through the power supply wire 22 into the internal circuit.

In the primitive cell shown in FIG. 4, the current that flows through the internal circuit from the power supply wire 22 flows into the source of the PMOS transistor MP2 or the source of the PMOS transistor MP3. The current is then discharged to the ground wire 21 through the drain of each of the PMOS transistors MP2, MP3, the drain and the source of the NMOS transistor MN2, and the drain and the source of the NMOS transistor MN3. At this time, since the ground wire 21 and the power supply wire 22 localize in one side of the sides of the primitive cell, the size of the loop formed by the current flowing through the primitive cell is smaller than the size of a single primitive cell.

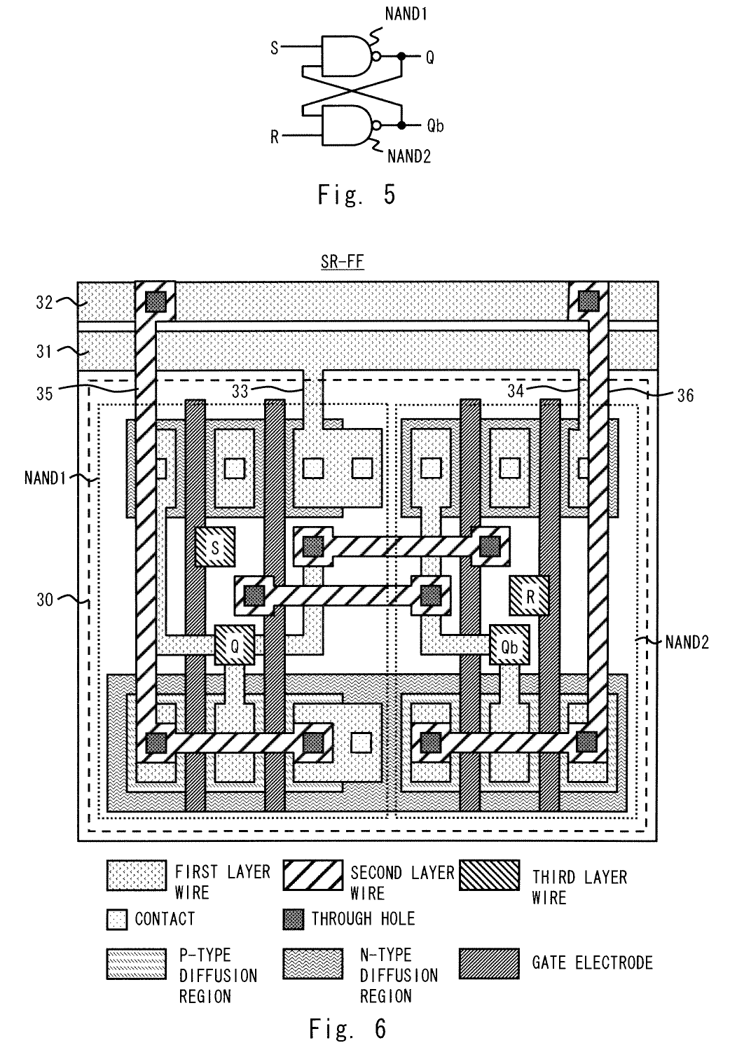

Next, a circuit diagram of a SRFF circuit is shown in FIG. 5. As shown in FIG. 5, the SRFF circuit includes a NAND1 and a NAND2. The NAND1 has a first input terminal serving as a set terminal S of the SRFF circuit, and a second input terminal connected to an output terminal Qb of the NAND2. Further, the NAND2 has a second input terminal serving as a reset terminal R of the SRFF circuit, and a first input terminal connected to an output terminal Q of the NAND1.

FIG. 6 shows a schematic diagram of a planar layout of the primitive cell including the SRFF circuit shown in FIG. 5 as the internal circuit. The primitive cell shown in FIG. 6 includes the NAND1 and the NAND2 constituting the SRFF circuit formed in an internal circuit forming region 30 where the internal circuit is formed. As shown in FIG. 6, the NAND1 and the NAND2 are substantially the same to the NAND circuit shown in FIG. 4. Further, the set terminal S, the reset terminal R, and the output terminals Q and Qb are formed in the internal circuit. The set terminal S, the reset terminal R, and the output terminals Q and Qb are connected to an input terminal or an output terminal of another primitive cell by wires formed in the upper layer of the primitive cell. Note that the internal circuit constitutes a transistor by a diffusion region formed of a P-type semiconductor (P-type diffusion region), a diffusion region formed of an N-type semiconductor (N-type diffusion region), and a gate electrode, and a first layer wire to a third layer wire, a contact, and a through hole form the wiring.

Further, as shown in FIG. 6, the primitive cell according to the present invention includes a ground wire 31 and a power supply wire 32. The ground wire 31 applies the ground voltage to the internal circuit, and the power supply wire 32 applies the power supply voltage to the internal circuit. Then, the ground wire 31 and the power supply wire 32 localize in one side of the sides of the primitive cell. Further, the ground wire 31 and the power supply wire 32 are arranged so as to traverse the primitive cell. Although the ground wire 31 and the power supply wire 32 are adjacent to each other in FIG. 6, the ground wire 31 and the power supply wire 32 may have other structure as long as they localize in one side of the primitive cell. For example, the ground wire 31 and the power supply wire 32 may be overlapped with each other. Further, the ground wire 31 includes branch ground wires 33 and 34 that connect the ground wire 31 and the internal circuit. The branch ground wires 33 and 34 draw the ground voltage supplied through the ground wire 31 into the internal circuit. Further, the power supply wire 32 includes branch power supply wires 35 and 36 that connect the power supply wire 32 and the internal circuit. The branch power supply wires 35 and 36 draw the power supply voltage supplied through the power supply wire 32 into the internal circuit.

In the primitive cell shown in FIG. 6, the current that flows through the internal circuit from the power supply wire 32 flows into each of the NAND1 and the NAND2. In this case, since the ground wire 31 and the power supply wire 32 localize in one side of the sides of the primitive cell, the loop formed by the current flowing through the primitive cell is smaller than the outer peripheral length of the NAND1 and the NAND2.

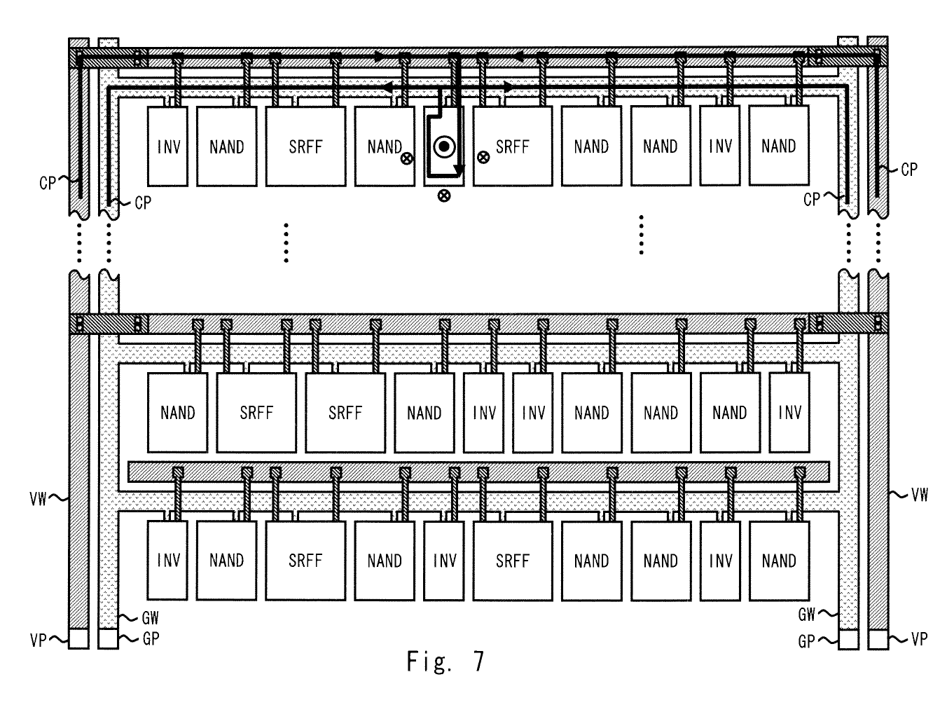

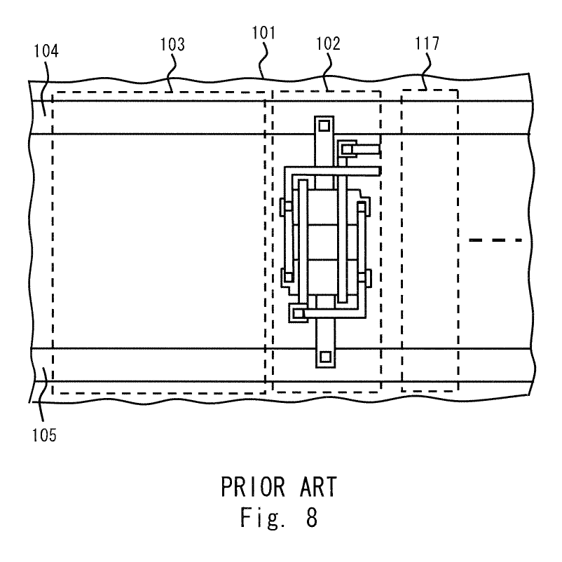

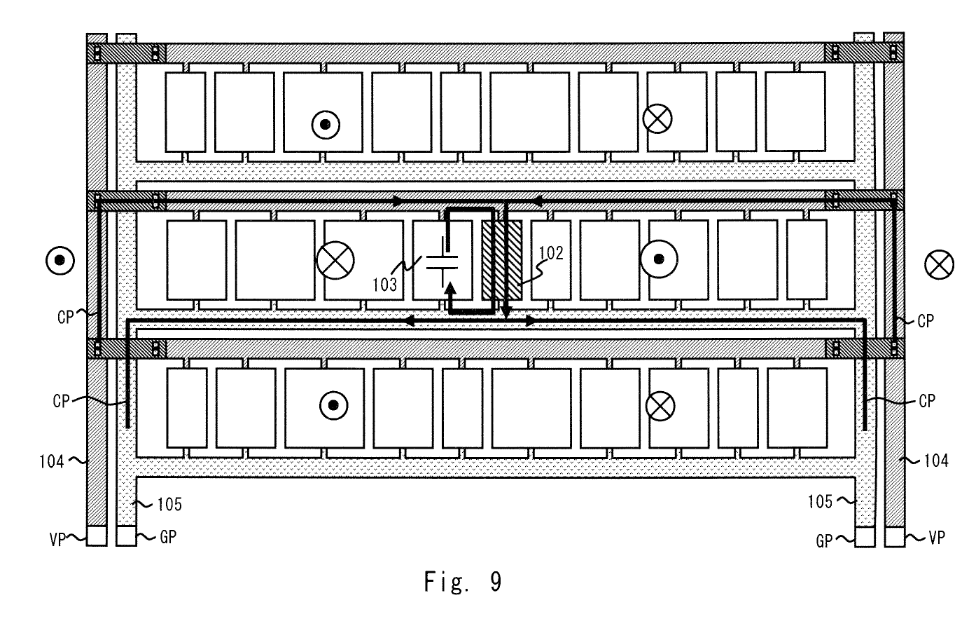

Next, a semiconductor device constituting a functional circuit using the primitive cells stated above will be described. FIG. 7 shows a schematic diagram of a planar layout of the semiconductor device including the functional circuit constituted by the primitive cells described in FIGS. 2, 4, and 6. As shown in FIG. 7, the semiconductor device includes inverter (INV) circuits, NAND circuits, and SRFF circuits serving as primitive cells, and the primitive cells constitute a functional circuit. In this case, the primitive cells are arranged in a plurality of lines. The primitive cells that are adjacent in each line include the power supply wire VW and the ground wire GW that are arranged adjacent to each other. Then, the power supply wire VW is connected to the power supply pad VP arranged on the semiconductor device, and is supplied with the power supply voltage from outside. Further, the ground wire GW is connected to the ground pad GP arranged on the semiconductor device.

Further, in FIG. 7, current paths CP of the current that flows through the power supply wire VW and the ground wire GW are illustrated. As shown in FIG. 7, by using the primitive cells according to the present invention, the size of the loop formed by the current path CP is limited to the size of one primitive cell. Further, the loop generates the magnetic field in the direction from the back side to the front side of the drawing inside the primitive cell, and the magnetic field in the direction from the front side to the back side of the drawing outside of the primitive cell.

From the above description, in the primitive cell according to the present invention, the ground wire 11 and the power supply wire 12 localize in one side of the sides of the cell. Thus, the loop of the current path is not formed between the power supply wire 12 and the ground wire 11. On the other hand, in the primitive cell according to the present invention, a current inlet and a current outlet of the internal circuit in the primitive cell are arranged in the side where the power supply wire 12 and the ground wire 11 localize. Thus, in the primitive cell according to the present invention, the loop of the current path is formed only in the internal circuit in the primitive cell. Accordingly, in the primitive cell according to the present invention, the loop of the current path is definitely made smaller than the area of one primitive cell, and the size of the loop of the current path can be greatly reduced compared with the conventional primitive cell. By reducing the size of the loop of the current path, EMI noise can be greatly reduced in the semiconductor device according to the present invention.

Further, since EMI noise can be reduced in the semiconductor device using the primitive cell according to the present invention, it is possible to prevent degradation of characteristics of an analog IC stacked with a semiconductor chip in which a functional circuit is constituted by primitive cells in SiP having semiconductor chips stacked therein.

Furthermore, using the primitive cell according to the present invention reduces EMI noise without arranging the bypass capacitor as in the primitive cell disclosed in Japanese Unexamined Patent Application Publication No. 2000-183286, thereby eliminating the circuit size of the bypass capacitor. In summary, using the primitive cell according to the present invention reduces the chip size of the semiconductor device.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all aim elements, even if amended later during prosecution.

For example, the layout of the internal circuit forming region is not limited to the exemplary embodiment stated above, but may be changed as appropriate.

What is claimed is:

1. A primitive cell comprising:
an internal circuit;
a power supply wire that applies a power supply voltage to the internal circuit; and
a ground wire that applies a ground voltage to the internal circuit,
wherein the power supply wire and the ground wire are arranged so as to be localized in one side of outer peripheral sides of the cell.

2. The primitive cell according to claim 1, wherein the power supply wire and the ground wire are arranged so as to traverse the cell.

3. The primitive cell according to claim 1, wherein the internal circuit includes at least two transistors, and the primitive cell is a minimum constitutional unit of a logic circuit.

4. The primitive cell according to claim 1, further comprising:
a branch power supply wire that diverges from the power supply wire and connects the internal circuit and the power supply wire; and
a branch ground wire that diverges from the ground wire and connects the internal circuit and the ground wire.

5. The primitive cell according to claim 1, wherein the power supply wire and the ground wire are connected to a power supply wire and a ground wire of another primitive cell that is arranged to be adjacent to the primitive cell.

6. A semiconductor device comprising a primitive cell, the primitive cell comprising:
an internal circuit;
a power supply wire that applies a power supply voltage to the internal circuit; and
a ground wire that applies a ground voltage to the internal circuit; wherein
the power supply wire and the ground wire are arranged so as to be localized in one side of outer peripheral sides of the cell, and
a plurality of primitive cells constitute a functional circuit.

7. The semiconductor device according to claim 6, wherein the power supply wire and the ground wire are arranged so as to traverse the cell.
